(19) United States
(12) Patent Application Publication
(10) Pub. No.: US 2024/0194582 A1
(43) Pub. Date: Jun. 13, 2024

(54) SEMICONDUCTOR PACKAGE AND METHOD OF MANUFACTURING THE SAME

(71) Applicant: Samsung Electronics Co., Ltd., Suwon-si (KR)

(72) Inventors: Seokkyu Lee, Suwon-si (KR); Jihye Shim, Suwon-si (KR); Kiseok Kim, Suwon-si (KR); Wonbin Shin, Suwon-si (KR)

(21) Appl. No.: 18/523,970

(22) Filed: Nov. 30, 2023

(30) Foreign Application Priority Data
Dec. 12, 2022 (KR) 10-2022-0172730

(51) Int. Cl. H01L 23/498; H01L 23/31

(52) U.S. Cl. CPC H01L 23/49894; H01L 23/3128; H01L 23/49816; H01L 23/49822; H01L 24/08; H01L 2224/08235

(57) ABSTRACT

A semiconductor package includes a redistribution substrate having a first surface and a second surface opposite to each other, and including a plurality of first photosensitive insulating layers and a plurality of redistribution layers disposed among the plurality of first photosensitive insulating layers; at least one semiconductor chip disposed on the first surface of the redistribution substrate and including a plurality of contact pads electrically connected to the plurality of redistribution layers; a protective insulating layer including a second photosensitive insulating layer disposed on the second surface of the redistribution substrate and having a plurality of contact holes, and a non-photosensitive insulating layer disposed on an outer surface of the second photosensitive insulating layer and an internal sidewall of each of the plurality of contact holes; and a plurality of under bump metallurgy (UBM) connectors each having a UBM pad disposed on the protective insulating layer and a UBM via disposed in a respective contact hole of the plurality of contact holes and electrically connected to the plurality of redistribution layers.

### CROSS-REFERENCE TO RELATED APPLICATION(S)

This application claims benefit of priority to Korean Patent Application No. 10-2022-0172730 filed on Dec. 12, 2022 in the Korean Intellectual Property Office, the disclosure of which is incorporated herein by reference in its entirety.

### BACKGROUND

Example embodiments of the present disclosure relate to a semiconductor package and a method of manufacturing the same.

To use a semiconductor package, including an integrated circuit, in an electronic product, a packaging technique has been actively researched. Recently, it has been important to ensure reliability of a package against thermal impact in a manufacturing process or a use environment for reducing a size and a weight.

### SUMMARY

An example embodiment of the present disclosure provides a semiconductor package having improved reliability.

An example embodiment of the present disclosure provides a method of manufacturing a semiconductor package having improved reliability.

According to an example embodiment of the present disclosure, a semiconductor package includes a redistribution substrate having a first surface and a second surface opposite to each other, and including a plurality of first photosensitive insulating layers and a plurality of redistribution layers disposed among the plurality of first photosensitive insulating layers, the plurality of redistribution layers electrically connected to each other; at least one semiconductor chip disposed on the first surface of the redistribution substrate and including a plurality of contact pads electrically connected to the plurality of redistribution layers; a protective insulating layer including a second photosensitive insulating layer disposed on the second surface of the redistribution substrate and having a plurality of contact holes, the second photosensitive insulating layer including a first surface facing and adjacent to the redistribution substrate and a second surface opposite the first surface; a non-photosensitive insulating layer buried in the second photosensitive insulating layer, wherein the non-photosensitive insulating layer is provided as an outer surface of the protective insulating layer and is adjacent to the second surface of the second photosensitive insulating layer; and a plurality of under bump metallurgy (UBM) connectors disposed on the protective insulating layer and connected to the plurality of redistribution layers through the plurality of contact holes, respectively. A side surface of the non-photosensitive insulating layer surrounds each of the plurality of contact holes from a plan view and has a first inclined surface inclined with respect to a surface of the plurality of redistribution layers in a first direction, and an internal sidewall of each of the plurality of contact holes of the second photosensitive insulating layer has a second inclined surface inclined with respect to the surface of the plurality of redistribution layers in a second direction opposite to the first direction.

According to an example embodiment of the present disclosure, which may be the same embodiment or a different embodiment as discussed above, a semiconductor package, includes a redistribution substrate having a first surface and a second surface opposite to each other, and including a plurality of insulating layers and a plurality of redistribution layers disposed among the plurality of insulating layers, the plurality of redistribution layers electrically connected to each other; at least one semiconductor chip disposed on the first surface of the redistribution substrate and having a plurality of contact pads electrically connected to the plurality of redistribution layers; a protective insulating layer including a photosensitive insulating layer disposed on the second surface of the redistribution substrate and having a plurality of contact holes, and a non-photosensitive insulating layer buried in the photosensitive insulating layer, wherein the non-photosensitive insulating layer is provided as an outer surface of the protective insulating layer; and a plurality of under bump metallurgy (UBM) connectors each including a UBM pad disposed on the protective insulating layer and a UBM via disposed in a respective contact hole of the plurality of contact holes and electrically connected to the plurality of redistribution layers. For each UBM via, the photosensitive insulating layer has a portion disposed between the UBM via and the non-photosensitive insulating layer in a direction parallel to the first surface of the redistribution substrate.

According to an example embodiment of the present disclosure, which may be the same embodiment or a different embodiment as discussed above, a semiconductor package includes a redistribution substrate having a first surface and a second surface opposite to each other, and including a plurality of first photosensitive insulating layers and a plurality of redistribution layers disposed among the plurality of first photosensitive insulating layers; at least one semiconductor chip disposed on the first surface of the redistribution substrate and including a plurality of contact pads electrically connected to the plurality of redistribution layers; a protective insulating layer including a second photosensitive insulating layer disposed on the second surface of the redistribution substrate and having a plurality of contact holes, and a non-photosensitive insulating layer disposed on an outer surface of the second photosensitive insulating layer and an internal sidewall of each of the plurality of contact holes; and a plurality of under bump metallurgy (UBM) connectors each having a UBM pad disposed on the protective insulating layer and a UBM via disposed in a respective contact hole of the plurality of contact holes and electrically connected to the plurality of redistribution layers.

According to an example embodiment of the present disclosure, which may be the same embodiment or a different embodiment as discussed above, a semiconductor package includes a redistribution substrate having a first surface and a second surface opposite to each other, and including a plurality of first photosensitive insulating layers and a plurality of redistribution layers disposed among the plurality of first photosensitive insulating layers; at least one semiconductor chip disposed on the first surface of the redistribution substrate and including a plurality of contact pads electrically connected to the plurality of redistribution layers; a protective insulating layer having a first surface facing the second surface of the redistribution substrate and a second surface opposite the first surface, and including a second photosensitive insulating layer disposed on the second surface of the redistribution substrate and having a plurality of contact holes, and a non-photosensitive insulating layer disposed at an outer surface of the second photosensitive insulating layer to form the second surface of the protective insulating layer; and a plurality of under bump metallurgy (UBM) connectors each having a UBM pad disposed on the protective insulating layer and a UBM via disposed in a respective contact hole of the plurality of contact holes and electrically connected to a redistribution signal line of the plurality of redistribution layers, wherein the non-photosensitive insulating layer contacts each UBM pad.

According to an example embodiment of the present disclosure, a method of manufacturing a semiconductor package includes preparing a redistribution substrate having a first surface and a second surface opposite to each other and including a plurality of first photosensitive insulating layers and a plurality of redistribution layers disposed among the plurality of first photosensitive insulating layers and electrically connected to each other; forming a second photosensitive insulating layer covering an outermost redistribution layer on the first surface of the redistribution substrate, wherein the outermost redistribution layer has a plurality of pad regions; partially removing a portion around the plurality of pad regions from the second photosensitive insulating layer; forming a non-photosensitive insulating layer by filling a non-photosensitive insulating material in the portion partially removed from the second photosensitive insulating layer; forming a plurality of contact holes in the second photosensitive insulating layer to expose the plurality of pad regions, respectively; and forming a plurality of under bump metallurgy (UBM) connectors connected to the plurality of pad regions, respectively, on the second photosensitive insulating layer.

According to an example embodiment of the present disclosure, a method of manufacturing a semiconductor package includes preparing a redistribution substrate having a first surface and a second surface opposite to each other and including a plurality of first photosensitive insulating layers and a plurality of redistribution layers disposed among the plurality of first photosensitive insulating layers and electrically connected to each other; forming a second photosensitive insulating layer covering an outermost redistribution layer on the first surface of the redistribution substrate, wherein the outermost redistribution layer has a plurality of pad regions; forming a plurality of contact holes exposing the plurality of pad regions, respectively, in the second photosensitive insulating layer; forming a non-photosensitive insulating layer on an outer surface of the second photosensitive insulating layer, on sidewalls of the plurality of contact holes, and on the plurality of pad regions; selectively removing a portion of the non-photosensitive insulating layer disposed on the plurality of pad regions; and forming a plurality of under bump metallurgy (UBM) connectors connected to the plurality of pad regions, respectively, on the second photosensitive insulating layer.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a diagram illustrating a semiconductor package according to an example embodiment of the present disclosure;

FIG. 2 is a plan diagram illustrating the semiconductor package illustrated in FIG. 1 taken along line I-I′;

FIG. 3 is an enlarged diagram illustrating portion “A1” of the semiconductor package illustrated in FIG. 1;

FIGS. 4A to 4D are cross-sectional diagrams illustrating main processes of a method of manufacturing the semiconductor package illustrated in FIG. 1;

FIGS. 5A to 5G are cross-sectional diagrams illustrating a process of forming a UBM layer (see FIG. 4C) of a method of manufacturing the semiconductor package illustrated in FIG. 1;

FIG. 6 is an enlarged cross-sectional diagram illustrating a portion of a semiconductor package according to an example embodiment of the present disclosure;

FIG. 7 is a cross-sectional diagram illustrating a semiconductor package according to an example embodiment of the present disclosure;

FIG. 8 is an enlarged cross-sectional diagram illustrating portion “A2” of the semiconductor package illustrated in FIG. 7;

FIGS. 9A to 9F are cross-sectional diagrams illustrating main processes of a method of manufacturing the semiconductor package (particularly, a process of forming an UBM layer) illustrated in FIG. 7;

FIG. 10 is a cross-sectional diagram illustrating a portion of a semiconductor package according to an example embodiment of the present disclosure; and

FIGS. 11 and 12 are cross-sectional diagrams illustrating a semiconductor package according to example embodiments of the present disclosure.

### DETAILED DESCRIPTION

Hereinafter, embodiments of the present disclosure will be described as follows with reference to the accompanying drawings.

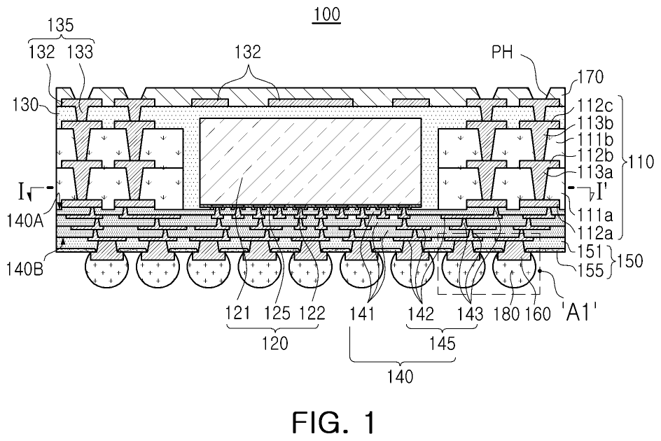

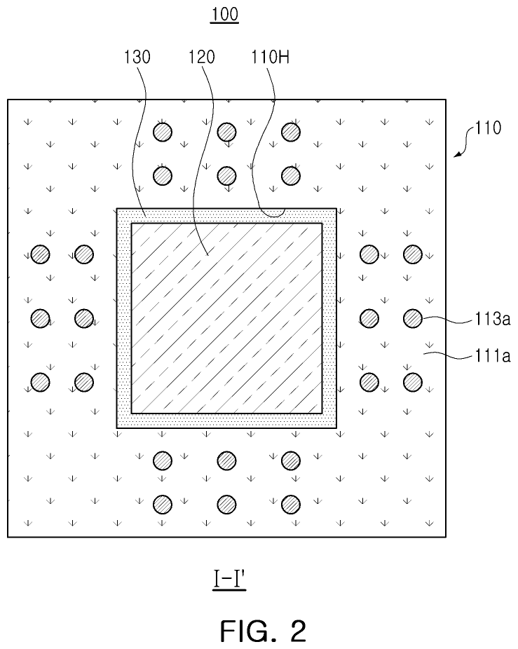

FIG. 1 is a diagram illustrating a semiconductor package according to an example embodiment. FIG. 2 is a plan diagram illustrating the semiconductor package illustrated in FIG. 1 taken along line I-I′.

Referring to FIGS. 1 and 2, a semiconductor package 100 in the example embodiment may include a redistribution substrate 140 including a first surface 140A and a second surface 140B disposed opposite to each other, a semiconductor chip 120 disposed on the first surface 140A of the redistribution substrate 140 and an encapsulant 130 encapsulating the semiconductor chip 120 on the first surface 140A of the redistribution substrate 140.

The redistribution substrate 140 may include a plurality of redistribution layers 145 disposed among the plurality of insulating layers 141, respectively, and connected to each other. Each redistribution layer 145 may include a plurality of redistribution patterns 142 disposed on the insulating layer 141 at the same vertical level, and a plurality of redistribution vias 143 at the same vertical level penetrating through the insulating layer 141 and connecting two adjacent redistribution patterns 142. For example, each redistribution via 143 may connect a redistribution pattern 142 above the via to a redistribution pattern 142 below the via. A set of redistribution vias 143 and redistribution patterns 142 at different vertical levels and connected in series with each other may be connected to a corresponding UBM connector 160 to form a redistribution signal line. Each redistribution signal line may connect a corresponding external connection conductor 180 to either one or more corresponding connection pads 122 of semiconductor chip 120 or one or more corresponding redistribution patterns 132, to transfer a voltage and/or signal. The redistribution substrate 140 employed in some example embodiments may include three insulating layers 141 and three redistribution layers 145, but in another example embodiment, the redistribution substrate 140 may include one or two layers or more layers. The insulating layer 141 may use a photosensitive insulating material such as photo-imagable dielectric (PID) resin. A photosensitive insulating material or layer as described herein refers to an insulating material or layer that is sensitive to light and can therefore be patterned using photolithography. A non-photosensitive insulating material or layer refers to an insulating material or layer that is not sensitive to light for the purposes of photolithography and which cannot be patterned using photolithography. Even when the insulating layer 141 includes multiple layers, the layer boundary may be indistinct depending on a material and a process of forming each insulating layer 141. In some descriptions here, a plurality of redistribution layers 145 will be described as a single redistribution layer (e.g., having a plurality of sub-redistribution layers). Also, in various sections of the specification, items may be described in the singular, even though a plurality of such items are included.

The semiconductor chip 120 may be disposed on the first surface 140A of the redistribution substrate 140. The semiconductor chip 120 employed in the example embodiment may include a semiconductor substrate 121 having an active surface, a plurality of connection pads 122 disposed on the active surface, and a passivation film 125 disposed on the active surface and opening the connection pads 122. The active surface of the semiconductor chip 120 may be disposed to oppose the redistribution substrate 140, and the connection pads 122 may be electrically connected to the redistribution layers 145.

The encapsulant 130 may protect a frame 110 and the semiconductor chip 20. For example, the encapsulant 130 may be formed to cover the semiconductor chip 120 together with the upper surface of the frame 110.

The semiconductor package 100 in the example embodiment may further include the frame 110, a backside wiring layer (RDL) 135, first and second protective insulating layers 150 and 170, a under bump metallurgy (UBM) layer 160 and an external connection conductor 180 (also described as an external connection terminal).

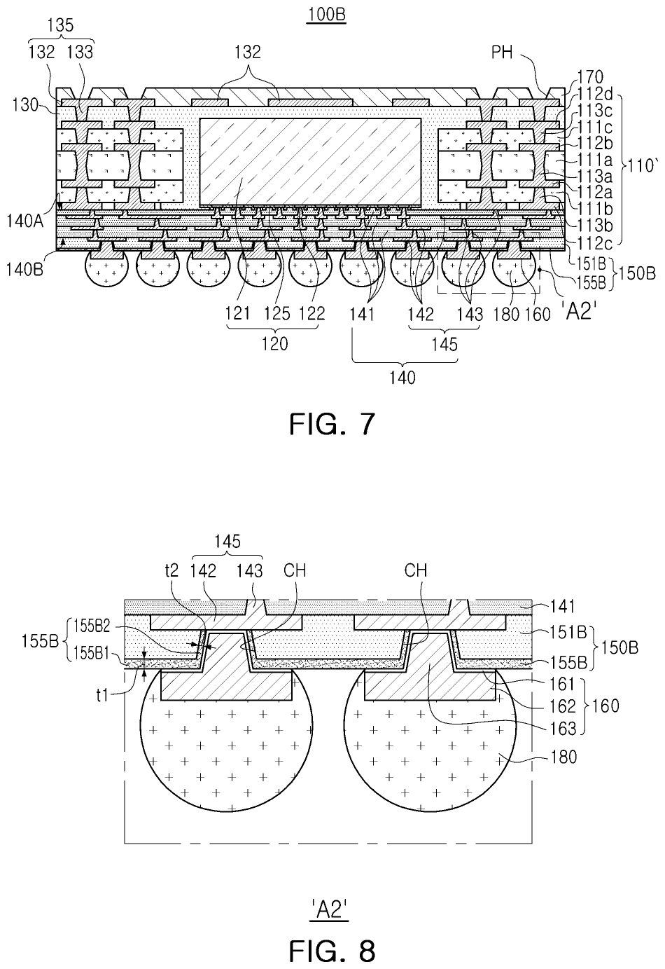

The frame 110 may be disposed on the first surface 140A of the wiring substrate 140 and may include a cavity 110H in which the semiconductor chip 120 is accommodated. The frame 110 may include a vertical interconnection portion connecting an upper surface and a lower surface thereof. The vertical interconnection portion employed in the example embodiment may have a multilayer wiring structure formed on the insulating layers 111a and 111b of the frame. The multilayer wiring structure may include first to third wiring layers 112a, 112b, and 112c and first and second wiring vias 113a and 113b connecting the first to third wiring layers 112a, 112b, and 112c, but an example embodiment thereof is not limited thereto. In example embodiments, the multilayer wiring structure may include a different number of layers and a different structure (see FIG. 7). The multilayer wiring structure of the frame 110 (in particular, the first wiring layer 112a) may be connected to the redistribution layers 145 of the redistribution substrate 140, and may be electrically connected to the semiconductor chip 120 through the redistribution layers 145.

In this example embodiment, the encapsulant 130 may extend to cover the upper surface of frame 110. The semiconductor package 100 may further include a backside wiring layer 135 disposed on the encapsulant 130 and electrically connected to the wiring structure (in particular, the third wiring layer 112c). The backside wiring layer 135 may include a redistribution pattern 132 disposed on the encapsulant 130 and a redistribution via 133 penetrating through a portion of the encapsulant 130 and connecting the third wiring layer 112c to the redistribution pattern 132.

The first and second protective insulating layers 150 and 170 may be disposed on the lower surface and the upper surface of the semiconductor package 100, respectively, to protect the components from external physical and chemical impacts.

The first protective insulating layer 150 may be disposed on the second surface 140B of the redistribution substrate 140, and the UBM layers 160 may be disposed on the first protective insulating layer 150. The UBM layers 160 may be connected to a portion of regions of the outermost redistribution pattern 142, respectively, through contact holes CH of the first protective insulating layer 150. The UBM layers 160 may also each be described herein as a UBM structure or a UBM connector, which connects a respective external connection conductor 180 to a redistribution layer 145.

The first protective insulating layer 150 may have a structure in which a photosensitive insulating material and a non-photosensitive insulating material are combined. Specifically, the first protective insulating layer 150 may be formed as a photosensitive insulating layer 151 identical or similar to the insulating layer 141 of the redistribution substrate 140, thereby improving efficiency and precision of the process of manufacturing the semiconductor package 100 and, by partially including a non-photosensitive insulating layer 155 having a relatively small difference in thermal expansion coefficient in relation to the UBM layers in the region in contact with the UBM layers 160, mechanical damage such as cracks due to thermal stress may be effectively prevented.

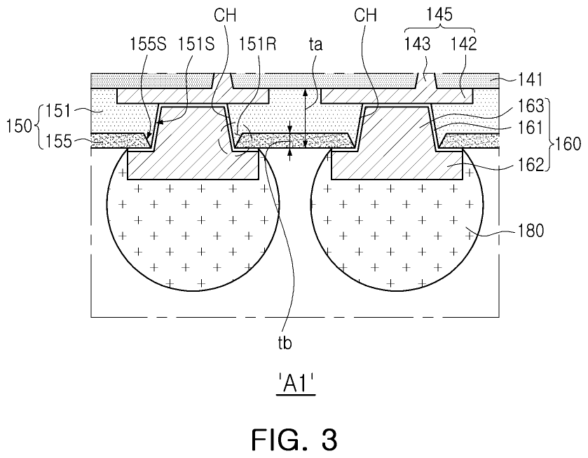

FIG. 3 is an enlarged diagram illustrating portion “A1” of the semiconductor package 100 illustrated in FIG. 1.

Referring to FIG. 3, the first protective insulating layer 150 employed in the example embodiment may include a photosensitive insulating layer 151 disposed on a second surface 140B of a redistribution substrate 140, and a non-photosensitive insulating layer 155 buried in the photosensitive insulating layer 151. The non-photosensitive insulating layer 155 may be formed at a surface of the photosensitive insulating layer 151 (e.g., at a bottom surface). The non-photosensitive insulating layer 155 may have an upper surface substantially coplanar with a lower surface of the photosensitive insulating layer 151 and may have a lower surface substantially coplanar with a lowermost surface of the photosensitive insulating layer 151. The photosensitive insulating layer 151 has a plurality of contact holes CH opening a portion of regions of the outermost redistribution pattern 142. Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise. Also, spatially relative terms, such as “beneath,” “below,” “lower,” “above,” “upper,” “top,” “bottom,” and the like, may be used herein for ease of description to describe positional relationships, such as illustrated in the figures, for example. It will be understood that the spatially relative terms encompass different orientations of the device in addition to the orientation depicted in the figures, and a lower surface or portion may be described as an upper surface or portion in relation to different elements at a different point in time (e.g., at a different point in a manufacturing process). Furthermore, it will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

The UBM layers 160 may include UBM pads 162 disposed on the first protective insulating layer 150, and UBM vias 163 connected to the UBM pads 162 and disposed in each of the plurality of contact holes CH. The UBM layers 160 may be formed by a plating process, and the seed layer 161 may be disposed on an interfacial surface between the UBM layer 160 and the first protective insulating layer 150. The UBM via 163, which as described below, may include a portion of the seed layer 161, may be connected to a portion of regions of the outermost redistribution pattern 142. A plurality of external connection conductors 180 may be disposed on the UBM layers 160, respectively. The UBM pad 162 and the external connection conductor 180 may contact a non-photosensitive insulating layer 155 provided at a lower surface of the first protective insulating layer 150. As such, the non-photosensitive insulating layer 155 contacting the UBM pad 162 and the external connection conductor 180 may have a relatively high degree of toughness (e.g., resistance to breakage) and a relatively high elongation (e.g., 100% or more) as compared to the photosensitive insulating layer 151 and accordingly, durability against thermal stress may be enhanced. For example, the non-photosensitive insulating layer 155 may have a higher degree of toughness than the photosensitive insulating layer 151. In addition, the non-photosensitive insulating layer 155 may have the same or a higher coefficient of thermal expansion (CTE) compared to the metal layers that form the UBM 160, as opposed to the photosensitive insulating layer 151, which has a lower CTE. Therefore, the elongation difference between the non-photosensitive insulating layer 155 and the UBM 160 due to heading and cooling may be small (e.g., a ratio of 1:1, or between 1:1 and 1.05:1).

In this example embodiment, since the first protective insulating layer 150 may be formed as a photosensitive insulating layer 151 and a contact hole CH may be formed in the photosensitive insulating layer 151, a contact hole CH having a fine size may be precisely formed with a fine pitch using a photolithography process.

However, due to the components having different coefficients of thermal expansion (e.g., the semiconductor chip 120, the redistribution layers 145, the insulating layer 141, the UBM layer 160, and the external connection conductor 180), thermal stress may be concentrated on the region around the UBM layer 160, and differently from the above example embodiment, when the first protective insulating layer 150 includes only the photosensitive insulating layer 151 (and not the non-photosensitive insulating layer 155), the photosensitive insulating layer 151 may have a relatively low degree of toughness and a relatively low elongation (e.g., the elongation of the photosensitive insulating layer 151 may be 80% or less of the elongation of the metal layers in the UBM as a result of heating), such that cracks may occur in the photosensitive insulating layer 151. Also, when the photosensitive insulating layer 151 (e.g., PID) is in contact with the UBM layer 160 (e.g., Cu) having high rigidity at a low temperature (e.g., −55° C.), stress due to the difference in thermal expansion coefficient may be applied to the photosensitive insulating layer, and damage such as cracks may easily occur.

To prevent such damage, the first protective insulating layer 150 employed in the example embodiment may include a non-photosensitive insulating layer 155 buried in the photosensitive insulating layer 151. A main contact between the UBM pad 162 and the external connection conductor 180 may be covered with a non-photosensitive insulating layer 155 rather than the photosensitive insulating layer 151.

To enhance resistance to thermal stress, the thickness tb of the non-photosensitive insulating layer 155 may be 10% or more of the total thickness ta of the first protective insulating layer 150. In example embodiments, the thickness tb of the non-photosensitive insulating layer 155 may be in a range of 10% to 40% of the total thickness ta of the first protective insulating layer 150.

As such, the non-photosensitive insulating layer 155 employed in the example embodiment may be a material having a higher elongation (e.g., higher CTE) than the photosensitive insulating layer 151 of the first protective insulating layer 150. For example, the non-photosensitive insulating layer 155 may be or include prepreg, Ajinomoto build-up film (ABF), FR-4, or bismaleimide triazine (BT). In example embodiments, the non-photosensitive insulating layer 155 may be or include an epoxy resin or an ABF resin. The photosensitive insulating layer 151 may be or include a positive photosensitive material. When the insulating layer 141 of the redistribution substrate 140 includes a photosensitive material, the photosensitive insulating layer 151 of the first protective insulating layer 150 may include or be formed of the same material as that of the insulating layer 141 of the redistribution substrate 140. For example, the photosensitive insulating layer 151 and the insulating layer 141 may include a PID material.

The non-photosensitive insulating layer may have a contact hole CH opening a partial region (e.g., the pad region) of the redistribution layers 145, and the contact hole CH may define the UBM via 163.

In an example embodiment, a side surface 155S surrounding the contact hole CH of the non-photosensitive insulating layer 155 may have a first inclined surface inclined in a first direction (e.g., to get wider in a direction toward the redistribution layers 145). The internal sidewall 151S of the contact hole CH provided by the photosensitive insulating layer 151 may have a second inclined surface inclined in a second direction opposite to the first direction (e.g., to get narrower in a direction toward the redistribution layers 145). When the photosensitive insulating layer 151 uses a positive photosensitive material as described above, the side surface 155S of the non-photosensitive insulating layer 155 and the internal sidewall 151S of the photosensitive insulating layer 151 may have inclined surfaces inclined in opposite directions.

The photosensitive insulating layer 151 may have a portion 151R disposed, for each UBM via 163, between the UBM via 163 and the non-photosensitive insulating layer 155 in a direction parallel to the first surface 140A or the second surface 140B of the redistribution substrate 140. The portion 151R may be disposed around the lower end region of the UBM via 163.

The UBM layer 160 may be formed in a contact hole of the first protective insulating layer by a general plating process, but the embodiments are not limited thereto. The external connection conductor 180 may physically and/or electrically connect the semiconductor package 100 to an external device such as a main board of an electronic device. The external connection conductor 180 may include or be formed of a low melting point metal, for example, solder such as tin (Sn)-aluminum (Al)-copper (Cu). The external connection conductor 180 may include multiple layers or a single layer. For example, the multiple layers may include or be copper pillars and solder, and the single layer may include or be tin-silver solder or copper.

The second protective insulating layer 170 may be disposed on the upper surface of the encapsulant 130 to cover the backside wiring layer 135. The second protective insulating layer 170 may have an opening PH for opening a portion of regions of the redistribution pattern 132, and a portion of open regions of the redistribution pattern 132 may be provided as pad regions. The second protective insulating layer 170 may be or include an insulating material. For example, the second protective insulating layer 170 may be or include prepreg, ABF, FR-4, BT, solder resist, or PID. In some embodiments, the second protective insulating layer 170 is formed of the same material as the non-photosensitive insulating layer 155. A surface treatment layer (not illustrated) formed by a plating process such as noble metal plating may be included in the open region of the backside redistribution pattern 132.

The semiconductor chip 120 employed in this example embodiment may include a semiconductor substrate 121 having an active surface and an inactive surface opposite to the active surface, and a plurality of active/passive elements (e.g., transistors) and a connection pad 122 connected to the same may be disposed on the active surface of the semiconductor substrate 121. For example, the semiconductor substrate 121 may be implemented as a single-element semiconductor substrate, a single element such as silicon or germanium, or a compound semiconductor substrate, a compound such as silicon carbide (SiC), gallium arsenide (GaAs), indium arsenide (InAs), and indium phosphide (InP). A passivation film 123 opening the connection pad 122 may be disposed on the active surface of the semiconductor substrate 121. For example, the passivation film 123 may be an oxide film or a nitride film, or may be a double layer of an oxide film and a nitride film.

The semiconductor chip 120 may include, for example, a memory chip such as a volatile memory (e.g., DRAM), a non-volatile memory (e.g., ROM), or a flash memory, or a logic chip such as a microprocessor, a microcontroller, an analog-to-digital converter, and an application-specific IC (ASIC).

The frame 110 may be an optional component and may further improve rigidity of the semiconductor package 100 depending on specific materials. As described above, the frame 110 may have a wiring structure as a vertical interconnection portion connecting upper and lower surfaces to each other. The semiconductor package 100 in one example embodiment may be used as a package on package (POP) type package. The semiconductor chip 120 disposed in the cavity 110H of the frame 110 may be disposed to be spaced apart from an internal sidewall of the frame 110 by a predetermined distance. A side surface of the semiconductor chip 120 may be surrounded by the frame 110.

As described above, the frame 110 may include a first insulating layer 111a in contact with the redistribution substrate 140, a first wiring layer 112a in contact with the redistribution substrate 140 and buried in the first insulating layer 111a, a second wiring layer 112b disposed on the side opposite to the side in which the first wiring layer 112a of the first insulating layer 111a is buried, a second insulating layer 111b disposed on the first insulating layer 111a and covering the second wiring layer 112b, and a third wiring layer 112c disposed on the second insulating layer 111b. The first to third wiring layers 112a, 112b, and 112c may be electrically connected to the connection pad 122. The first to third wiring layers 112a, 112b, and 112c may be electrically connected to each other through first to second wiring vias 113a and 113b penetrating the first and second insulating layers 111a and 111b, respectively.

When the first wiring layer 112a is buried in the first insulating layer 111a, as in the example embodiment of FIGS. 1-3, the stepped difference caused by the thickness of the first wiring layer 112a may be reduced, such that an insulation distance of the redistribution substrate 140 may become constant. In the first wiring layer 112a, a lower surface of the first insulating layer 111a and a lower surface of the first wiring layer 112a may have a stepped difference as the first insulating layer is recessed into the first wiring layer 112a. In this case, the material forming the encapsulant 130 may be prevented from bleeding and contaminating the first wiring layer 112a. The frame 110 may be manufactured to have a sufficient thickness through a substrate process, whereas the redistribution substrate 140 may be manufactured through a semiconductor process to have a thin thickness, and accordingly, a thickness of each of the first to third wiring layers 112a, 112b, and 112c of the frame 110 may be greater than a thickness of each redistribution pattern 142 of the redistribution substrate 140.

The first and second insulating layers 111a and 111b may include or be formed of a thermosetting resin such as epoxy resin, a thermoplastic resin such as polyimide, or a composite resin including inorganic fillers and/or glass fiber, glass cloth, and glass fabric in the resins. In example embodiments, the first and second insulating layers 111a and 111b may include or be formed of prepreg, Ajinomoto build-up film (ABF), FR-4, and bismaleimide triazine (BT).

The first to third wiring layers 112a, 112b, and 112c may redistribute the connection pad 22 of the semiconductor chip 20. The first to third wiring layers 112a, 112b, and 112c may include or be formed of a conductive material such as copper (Cu), aluminum (Al), silver (Ag), tin (Sn), gold (Au), nickel (Ni), lead (Pb), titanium (Ti) or alloys thereof. The first and second wiring vias 113a and 113b may electrically connect the first to third wiring layers 112a, 112b and 112c formed on different insulating layers 111a and 111b to each other and may form a wiring structure having an Interlayer connection path within the frame 110. The above-described conductive material may also be used as a material for forming the first and second wiring vias 113a and 113b. In example embodiments, the first and second wiring vias 113a and 113b may have a structure integrated with the second and third wiring layers 112b and 112c through the same process (e.g., a plating process), respectively.

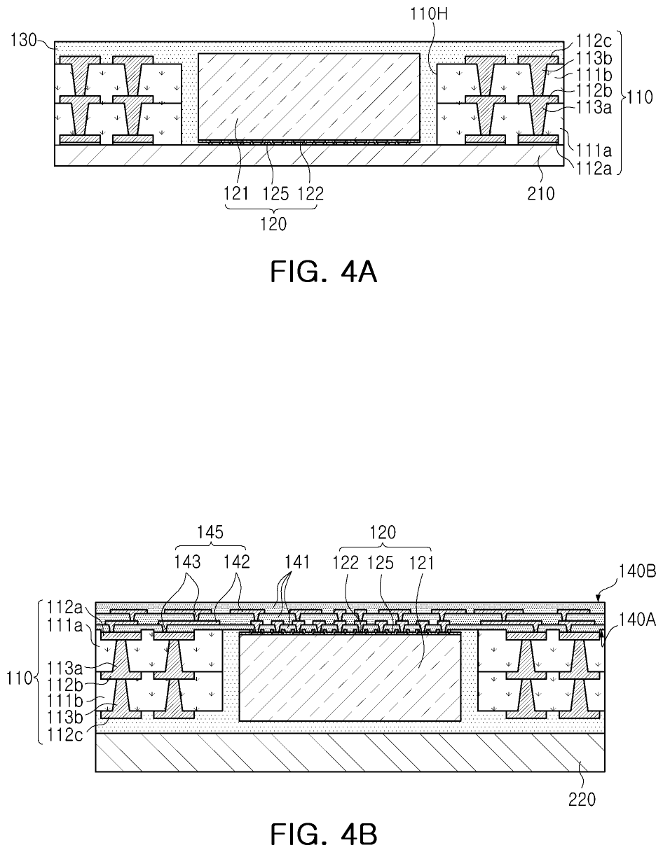

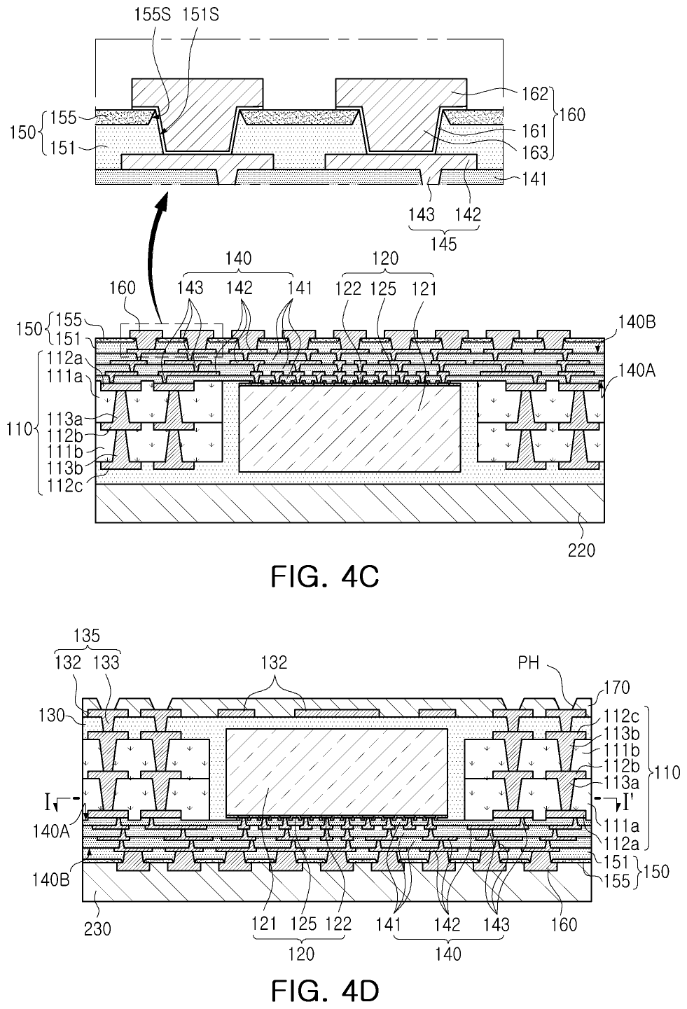

FIGS. 4A to 4D are cross-sectional diagrams illustrating main processes of a method of manufacturing the semiconductor package illustrated in FIG. 1.

Referring to FIG. 4A, a frame 110 having a cavity 110H may be disposed on the first carrier film 210, the semiconductor chip 120 may be accommodated in the cavity 110H, and the encapsulant 130 may be formed.

As described above, the frame 110 employed in the example embodiment may include a wiring structure together with first and second insulating layers 111a and 111b, and the wiring structure may include three-layered wiring patterns 112a, 112b and 112c and wiring vias 113a and 113b connecting the wiring patterns. A first carrier film 210 may be attached to the lower side of the first insulating layer 111a. For example, the first carrier film 210 may be an adhesive tape including epoxy resin.

The semiconductor chip 120 may be disposed such that the surface on which the connection pad 122 is formed may face the first carrier film 210. The encapsulant 130 encapsulating the semiconductor chip 120 may be formed using the above-described encapsulation material. The encapsulant 130 may cover the semiconductor chip 120 and the frame 110.

Thereafter, referring to FIG. 4B, the second carrier film 220 may be attached to the upper surface of the encapsulant 130 (the upper surface based on the orientation in FIG. 4A, which may be considered a lower surface in the step shown in FIG. 4B after the device under manufacture is flipped), the first carrier film 210 may be removed, and the redistribution substrate 140 may be formed on the removed surface.

This process may include a process of forming an insulating layer 141 using a lamination or a coating method, a process of forming via holes in the insulating layer 141, and a process of forming a first redistribution pattern 142 and a redistribution vias 143 by electroplating or electroless plating. A photosensitive insulating layer (also referred to as a “first photosensitive insulating layer”) such as PID may be used as the insulating layer 141, and in this case, a via hole may be formed with a fine pitch using a photolithography process.

Thereafter, referring to FIG. 4C, a first protective insulating layer 150 and a UBM layer 160 may be formed on the second surface 140B of the redistribution substrate 140.

First, the first protective insulating layer 150 may be formed by forming a photosensitive insulating layer 151 (also referred to as a “second photosensitive insulating layer”), and partially burying the non-photosensitive insulating layer 155 in the photosensitive insulating layer 151. Subsequently, a plurality of contact holes for opening a partial region of the redistribution pattern 142 may be formed in the photosensitive insulating layer 151 using a photolithography process, and a UBM layer 160 connected to a partial region of the redistribution pattern 142 through a contact hole may be formed on the first protective insulating layer 150.

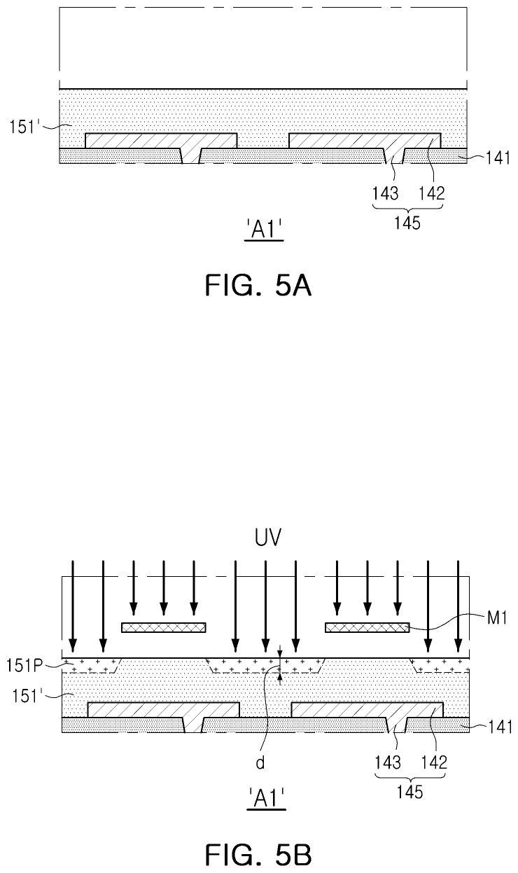

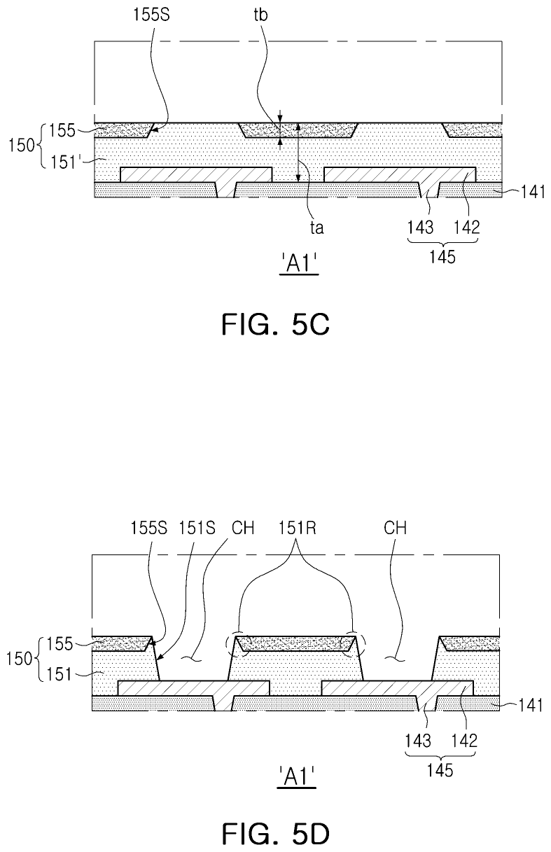

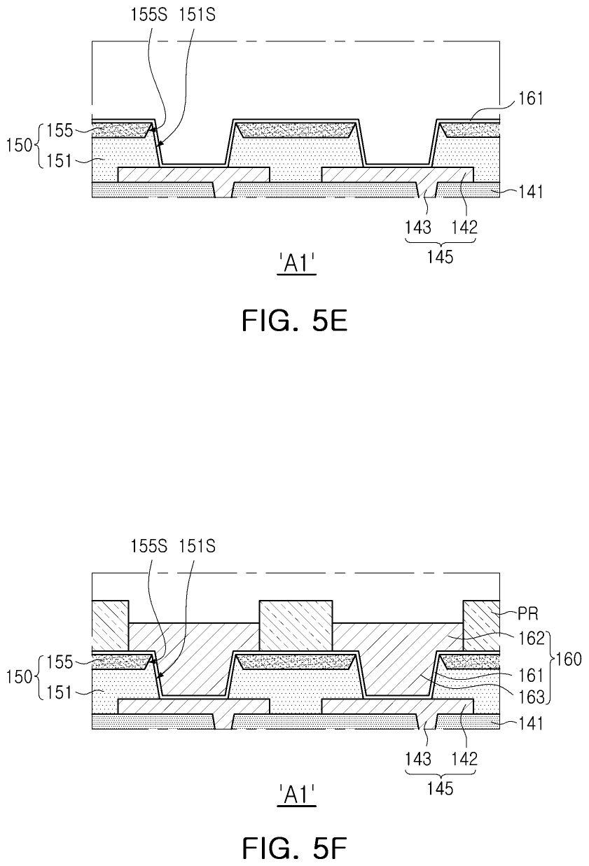

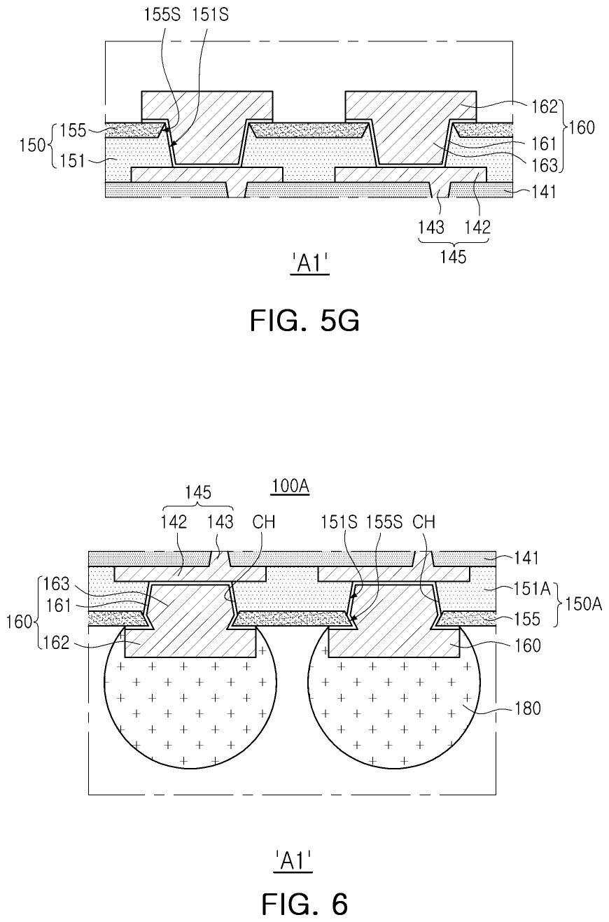

Hereinafter, the processes included in FIG. 4C will be described in greater detail with reference to FIGS. 5A to 5G.

FIGS. 5A to 5G are cross-sectional diagrams illustrating a process of forming the first protective insulating layer 150 and the UBM layer 160 (see FIG. 4C), and each cross-sectional diagram illustrates a region corresponding to the enlarged diagram in FIG. 4C.

Referring to FIG. 5A, a second photosensitive insulating layer 151′ (also described as a preliminary photosensitive insulating layer) covering the outermost redistribution pattern 142 may be formed on the second surface 140B of the redistribution substrate 140.

The second photosensitive insulating layer 151′ may include or be formed of a positive photosensitive material. When the insulating layer 141 of the redistribution substrate 140 includes a photosensitive material, the second photosensitive insulating layer 151′ of the first protective insulating layer 150 may include the same material as that of the insulating layer 141 of the redistribution substrate 140. For example, the second photosensitive insulating layer 151′ and the insulating layer 141 may each be a PID material. For example, the second photosensitive insulating layer 151′ may have a thickness (e.g., maximum thickness) ranging from 20 μm to 100 μm. In an example embodiment, the second photosensitive insulating layer 151′ may be provided as a portion in which a contact hole is later formed to result in in the first protective insulating layer 150. Accordingly, a contact hole having a fine size may be precisely formed with a fine pitch using a photolithography process.

Subsequently, referring to FIG. 5B, a region around where the contact hole is later formed is partially removed from the second photosensitive insulating layer 151′.

The redistribution pattern 142 may have a pad region connected to the UBM layer (“160” in FIG. 5F) in a subsequent process, and in the step shown in FIG. 5B, a region in the second photosensitive insulating layer 151′, around where the contact hole is later formed, may be selectively removed. This selective removal may be performed using a first mask M1 for opening a region to be exposed. The selective removal in the example embodiment may be performed using a partial photolithography process using a partial exposure and development, for example using UV light. In the partial exposure, only the portion 151P corresponding to a predetermined depth d from the upper surface of the second photosensitive insulating layer 151′ may react by adjusting exposure energy and/or exposure time. Accordingly, the partially exposed portion 151P formed to a predetermined depth d may be removed through a developing process and a desired recess region may be formed in a region around the area where the contact hole is later formed. The recess region may define a formation region of a non-photosensitive insulating layer (“155” in FIG. 5C) to be formed in a subsequent process. In example embodiments, the formation depth d of the exposed portion 151P may be in the range of 10% to 40% of the thickness (e.g., maximum thickness) of the second photosensitive insulating layer 151′.

Since the recess region formed in this example embodiment is formed by partially exposing a positive photosensitive material, the recess region may have a shape of which a width may decrease downwardly. That is, the side surface of the recess region may have an inclined surface that tapers in a direction toward the redistribution layers 145.

The recess region may be formed on the upper surface of the second photosensitive insulating layer 151′ in a region other than a region where a contact hole is later formed. In example embodiments, the recess region may be selectively formed in a region in contact with the UBM layer (“160” in FIG. 5F) in which stress is concentrated. For example, the recess region is formed in regions to be in contact with the UBM pad (“162” in FIG. 5F) in the upper surface region of the photosensitive insulating layer 151, and may be provided as a plurality of recess regions separated from each other.

Thereafter, referring to FIG. 5C, a non-photosensitive insulating layer 155 may be formed by filling a non-photosensitive insulating material in a recess region partially removed from the second photosensitive insulating layer 151′.

In this process, a non-photosensitive insulating material may be coated to fill the recess region and also cover the second photosensitive insulating layer 151′, a non-photosensitive insulating layer 155 may be formed by curing the non-photosensitive insulating material, and a polishing process may be performed to expose a portion of the second photosensitive insulating layer 151. The non-photosensitive insulating layer 155 may have an upper surface substantially coplanar with an upper surface of the second photosensitive insulating layer 151′. Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise. In example embodiments, after coating the non-photosensitive insulating material, a portion of the non-photosensitive insulating material may be removed from the upper surface of the second photosensitive insulating layer 151′, and the non-photosensitive insulating layer 155 may be formed by curing the non-photosensitive insulating material remaining in the recess region.

The non-photosensitive insulating layer 155 may be a material having higher elongation (e.g., higher CTE) than that of the photosensitive insulating layer 151. For example, the non-photosensitive insulating layer 155 may include prepreg, ABF, FR-4, or BT. In example embodiments, the thickness tb of the non-photosensitive insulating layer 155 may be in a range of 10% to 40% of the total thickness ta (e.g., maximum thickness, in a vertical direction) of the first protective insulating layer 150.

Subsequently, referring to FIG. 5D, a plurality of contact holes CH may be formed in the second photosensitive insulating layer 151′ to form the photosensitive insulating layer 151.

A partial region of the redistribution pattern 142 may be exposed through a contact hole CH formed in the second photosensitive insulating layer 151′, and the exposed region may be provided as a pad region to be connected to the UBM layer 160 to be formed in a subsequent process.

The process of forming such a contact hole CH may be formed by performing a photolithography process. Each of the contact holes CH may have a width decreasing downwardly (e.g., tapered in a direction toward the exposed redistribution pattern 142). The internal sidewall of the contact hole CH may have an inclined surface inclined in the direction that tapers in the direction toward the redistribution layers 145.

As such, the side surface 155S of the non-photosensitive insulating layer 155 and the internal sidewall 151S of the photosensitive insulating layer 151 may have inclined surfaces inclined in opposite directions. A side surface 155S surrounding the contact hole CH of the non-photosensitive insulating layer 155 may have a first inclined surface inclined in a first direction going toward the redistribution layers 145, and the internal sidewall 151S of the contact hole CH provided by the photosensitive insulating layer 151 may have a second inclined surface inclined in a second direction opposite to the first direction. Also, the photosensitive insulating layer 151 may have a portion 151R disposed between the UBM via 163 and the non-photosensitive insulating layer 155 in a direction parallel to the first surface 140A or the second surface 140B of the redistribution substrate 140.

Thereafter, a plurality of UBM layers 160 each connected to the pad region of the redistribution pattern 142 open to the second photosensitive insulating layer 151 may be formed. For example, a plurality of UBM layers 160 may be formed through a series of processes in FIGS. 5E to 5G.

First, referring to FIG. 5E, a seed layer 161 may be formed on the first protective insulating layer 150 in which a contact hole CH is formed. The seed layer 161 may be formed over the upper surface of the first protective insulating layer 150, the internal sidewall of the contact hole CH, and the region of the redistribution pattern 142 exposed on the bottom surface. For example, the seed layer 161 may include or be formed of Ti/W (e.g., a titanium/tungsten alloy) or Ti/Cu (e.g., a titanium/copper alloy).

Subsequently, referring to FIG. 5F, a photoresist pattern PR having an opening for the UBM layer 160 may be formed on the seed layer 161, and the UBM layer 160 may be formed using the photoresist pattern PR.

The UBM layer 160 may be formed by a plating layer such as Cu. This plating process may be performed by immersion plating, electroless plating or electroplating. The portion of the UBM layer 160 formed in the contact hole CH, that includes both the seed layer 161 material and the plating material may be referred to as a UBM via 163, and the portion of the UBM layer 160 formed above the contact hole CH, that includes both the seed layer 161 material and the plating material may be referred to as the UBM pad 162. A similar terminology may be used for later-described embodiments. A partial region of the UBM pad 162 may contact the non-photosensitive insulating layer 155 buried in the photosensitive insulating layer 151. When an external connection conductor is formed on the UBM pad 162, the non-photosensitive insulating layer 155 may also contact the external connection conductor. Even when stress due to a difference in coefficient of thermal expansion is concentrated around the UBM pad 162, the non-photosensitive insulating layer 155 in contact with the UBM pad 162 and the external connection conductor may have a relatively high degree of toughness and a relatively high elongation or CTE (e.g., 100% or more compared to the materials of the UBM pad 162 or external connection conductor), such that durability of the semiconductor package may be enhanced.

Thereafter, referring to FIG. 5G, the photoresist pattern PR may be removed, and a portion of the seed layer 161 exposed to the removed region may be removed.

The photoresist pattern PR may be removed by a lift-off process. For example, the photoresist pattern PR may be removed using a suitable process such as an ashing process, an etching process, or a combination thereof. Additionally, a portion of the seed layer 161 exposed through etching may be removed.

As such, through the processes described with reference to FIGS. 5A to 5G, the package structure illustrated in FIG. 4c described above may be prepared.

Thereafter, referring to FIG. 4D, a third carrier film 230 may be formed on the surface of the first protective insulating layer 150, the device under manufacture may be flipped over, and the second carrier film 220 may be removed from the encapsulant 130, such that a backside wiring layer 135 may be formed, and a second protective insulating layer 170 may be formed on the encapsulant 130 to cover the backside wiring layer 135.

First, after removing the second carrier film 220, a hole through which a partial region of the third wiring layer 112c is opened may be formed in the encapsulant 130. This process may form a hole using a laser drill process, but an example embodiment thereof is not limited thereto. For example, when the encapsulant 130 is formed of a photosensitive material such as PID, a photolithography process may be used. A backside wiring layer 135 connected to the open region of the third wiring layer 112c may be formed on the upper surface of the encapsulant 130 using a plating process. Specifically, the backside wiring layer 135 may include a redistribution pattern 132 disposed on the upper surface of the encapsulant 130 and a redistribution via 133 connecting the redistribution pattern 132 to the third wiring layer 112c through the hole. The redistribution via 133 and the redistribution pattern 132 may have an integrated structure formed by a plating process.

Thereafter, a second protective insulating layer 170 may be formed on the encapsulant 130 to cover the backside wiring layer 135, and an opening PH exposing a partial region of the redistribution pattern 132 may be formed in the second protective insulating layer 170.

Subsequently, the device under manufacture may be flipped again, the third carrier film 230 may be removed, and external connection conductors (“180” in FIG. 3) may be formed on the UBM layer 160 (e.g., on UBM pads 162). The process of forming the external connection conductor 180 may be performed after the process in FIG. 4D, or in other embodiments, after the process in FIG. 5G and before the process in FIG. 4D. The external connection conductors 180 may include or be formed of a low melting point metal, for example, solder such as tin (Sn)-aluminum (Al)-copper (Cu). The external connection conductors 180 may include multiple layers or a single layer. For example, the multiple layers may include or be copper pillars and solder, and the single layer may include or be tin-silver solder or copper.

FIG. 6 is an enlarged cross-sectional diagram illustrating a portion of a semiconductor package according to an example embodiment, corresponding to portion “A1” of the semiconductor package in FIG. 1.

Referring to FIG. 6, the semiconductor package 100A in the example embodiment may be configured similarly to the example embodiment illustrated in FIG. 3 other than the configuration in which the photosensitive insulating layer 151A may be removed from the side surface of the non-photosensitive insulating layer 155. Accordingly, the description in the example embodiment illustrated in FIG. 3 may be combined with the description in the example embodiment unless otherwise indicated.

The first protective insulating layer 150A employed in this example embodiment may include a photosensitive insulating layer 151A disposed on the second surface 140B of the redistribution substrate 140 and a non-photosensitive insulating layer 155 on the photosensitive insulating layer 151A. Similarly to the aforementioned example embodiment, the non-photosensitive insulating layer 155 in contact with the UBM pad 162 and the external connection conductor 180 may have a relatively high degree of toughness and a relatively high elongation (e.g., 100%) as compared to the photosensitive insulating layer 151A, durability against thermal stress may improve. In example embodiments, the thickness tb of the non-photosensitive insulating layer 155 may be in the range of 10% to 40% of the total thickness ta of the first protective insulating layer 150.

The first protective insulating layer 150A may have a plurality of contact holes CH opening a portion of regions of the outermost redistribution pattern 142. In this example embodiment, differently from the aforementioned example embodiment, the photosensitive insulating layer portion may be removed from the side surface 155S of the non-photosensitive insulating layer 155 in the process of forming the contact hole CH (see FIG. 5D), and accordingly, as illustrated in FIG. 6, the side surface 155S of the non-photosensitive insulating layer 155 may be in contact with the UBM via 163. In example embodiments, a portion (e.g., a portion adjacent to the upper surface) of the side surface 155S of the non-photosensitive insulating layer 155 may be in contact with the UBM via 163.

An upper region of the plurality of contact holes CH may have sidewalls defined by a photosensitive insulating layer 151A, and a lower region of the plurality of contact holes CH may have sidewalls defined by a non-photosensitive insulating layer 155. In this example embodiment, the height of the upper region of each contact hole CH may be greater than the height of the lower region thereof. That is, the thickness (ta-tb) of the photosensitive insulating layer 151A may be greater than the thickness tb of the non-photosensitive insulating layer 155, but embodiments thereof are not limited thereto.

Even in this example embodiment, the side surface 155S surrounding the contact hole CH of the non-photosensitive insulating layer 155 may have a first inclined surface inclined inward in a first direction toward the redistribution layers 145. The internal sidewall 151S of the contact hole CH provided by the photosensitive insulating layer 151A may have a second inclined surface inclined in a second direction opposite to the first direction (e.g., outward in a direction toward the redistribution layers 145). As such, the side surface 155S of the non-photosensitive insulating layer 155 and the internal sidewall 151S of the photosensitive insulating layer 151 may have surfaces inclined in opposite directions.

The process of forming the first protective insulating layer 150A and the UBM layer 160 in the example embodiment of FIG. 6 may be performed similarly to the examples in FIGS. 5A to 5G other than the configuration in which in FIG. 6, a portion of the photosensitive insulating layer 151A is removed from the side surface 155S of the non-photosensitive insulating layer 155 when the contact hole CH is formed (see FIG. 5D). In this example embodiment, as illustrated in FIG. 6, for the non-photosensitive insulating layer 155 formed at the surface of the photosensitive insulating layer 151A, the non-photosensitive insulating layer 155 may be disposed on the photosensitive insulating layer 151A rather than being buried in the photosensitive insulating layer 151A. In example embodiments, when the recess region in which the non-photosensitive insulating layer 155 is buried in the photosensitive insulating layer 151A is divided into a plurality of recess regions, a partial region of the non-photosensitive insulating layer 155 spaced apart from the contact hole CH may still be buried in the photosensitive insulating layer 151A even in the final structure.

FIG. 7 is a cross-sectional diagram illustrating a semiconductor package according to an example embodiment.

Referring to FIG. 7, the semiconductor package 100B in the example embodiment illustrated in FIG. 7 may be configured similarly to the example embodiment illustrated in FIGS. 1 to 3 other than the configuration in which the structure of the first protective insulating layer is different, and the wiring structure of the frame 110′ is different. Accordingly, the description in the example embodiment illustrated in FIGS. 1 to 3 may be combined with the description in the example embodiment of FIG. 7 unless otherwise indicated.

The frame 110′ employed in this example embodiment may have a different wiring structure from the frame 110 in the aforementioned example embodiment. Specifically, the frame 110′ may include a first insulating layer 111a, a first wiring layer 112a disposed on one surface of the first insulating layer 111a, a second wiring layer 112b disposed on the other surface of the first insulating layer 111a, a second insulating layer 111b disposed on one surface of the first insulating layer 111a to cover at least a portion of the first wiring layer 112a, a third wiring layer 112c disposed on a surface opposite to the side in which the first wiring layer 112a of the second insulating layer 111b is buried, a third insulating layer 111c disposed on the other surface of the first insulating layer 111a and covering at least a portion of the second wiring layer 112b, a fourth wiring layer 112d disposed on a surface opposite to the side on which the second wiring layer 112b of the third insulating layer 111c is buried, a first wiring via 113a penetrating the first insulating layer 111a and electrically connecting the first and second wiring layers 112a and 112b to each other, a second wiring via 113b penetrating the second insulating layer 111b and electrically connecting the first and third wiring layers 112a and 112c to each other, and a third wiring via 113c penetrating the third insulating layer 111c and electrically connecting the second and fourth wiring layers 112b and 112d. Since the frame 110′ employed in this example embodiment has a larger number of wiring layers 112a, 112b, 112c, and 112d, the redistribution layers 145 of the redistribution substrate 140 may be further simplified.

The first insulating layer 111a may have a thickness greater than those of the second insulating layer 111b and the third insulating layer 111c. Basically, the first insulating layer 111a may have a relatively thick thickness to maintain rigidity, and the second insulating layer 111b and the third insulating layer 111c may be included to form a larger number of wiring layers 112c and 112d. The first insulating layer 111a may include an insulating material different from that of the second insulating layer 111b and the third insulating layer 111c.

FIG. 8 is an enlarged cross-sectional diagram illustrating portion “A2” of the semiconductor package illustrated in FIG. 7.

Referring to FIGS. 7 and 8, the first protective insulating layer 150B employed in the example embodiment may include a photosensitive insulating layer 151B disposed on the second surface 140B of the redistribution substrate 140 and having a plurality of contact holes CH, and a non-photosensitive insulating layer 155B disposed on an upper surface of the photosensitive insulating layer 151B and internal sidewalls of the plurality of contact holes CH, respectively. Part of the non-photosensitive insulating layer 155B may therefore be formed at a surface of the photosensitive insulating layer 151B. The non-photosensitive insulating layer 155B may be conformally formed on the photosensitive insulating layer 151B.

In this example embodiment, the UBM layer 160 may not contact the photosensitive insulating layer 151B due to the non-photosensitive insulating layer 155B. Thermal stress may be concentrated in the region around the UBM layer 160, but since the non-photosensitive insulating layer 155B has a relatively high degree of toughness and a relatively high elongation (e.g., 100% or more) as compared to the photosensitive insulating layer 151B, durability of the semiconductor package 100B may improve.

To enhance resistance to thermal stress, the thickness tb of the non-photosensitive insulating layer 155B may be in the range from 10% to 40% of the total thickness ta of the first protective insulating layer 150B. For example, the non-photosensitive insulating layer 155B may include prepreg, ABF, FR-4, or BT. In an example embodiment, the photosensitive insulating layer 151 may include a positive photosensitive material. When the insulating layer 141 of the redistribution substrate 140 includes a photosensitive material, the photosensitive insulating layer 151B of the first protective insulating layer 150B may include or be formed of the same material as that of the insulating layer 141 of the redistribution substrate 140. For example, the photosensitive insulating layer 151B and the insulating layer 141 may include or be formed of a PID material.

The non-photosensitive insulating layer 155B employed in the example embodiment of FIGS. 7 and 8 may include a first portion 155B1 disposed horizontally and on an upper surface of the photosensitive insulating layer 151B and a second portion 155B2 connected to the first portion 155B1 and disposed on internal sidewalls of the plurality of contact holes CH, respectively. In example embodiments, as illustrated in FIG. 8, the second portion 155B2 of the non-photosensitive insulating layer 155B may have a thickness t2 (e.g., in a direction perpendicular to the surface of photosensitive insulating layer 151B on which it is disposed) smaller than the thickness t1 of the first portion 155B1 (e.g., in a direction perpendicular to the surface of photosensitive insulating layer 151B on which it is disposed).

As for the first protective insulating layer 150B, similarly to the aforementioned example embodiment, by forming the photosensitive insulating layer 151B as a basic structure, efficiency and precision of the process of manufacturing the semiconductor package 100 may improve, and by including the non-photosensitive insulating layer 155B having a relatively small difference in thermal expansion coefficient in a region in contact with the UBM layers 160, mechanical damages such as cracks due to thermal stress may be effectively prevented.

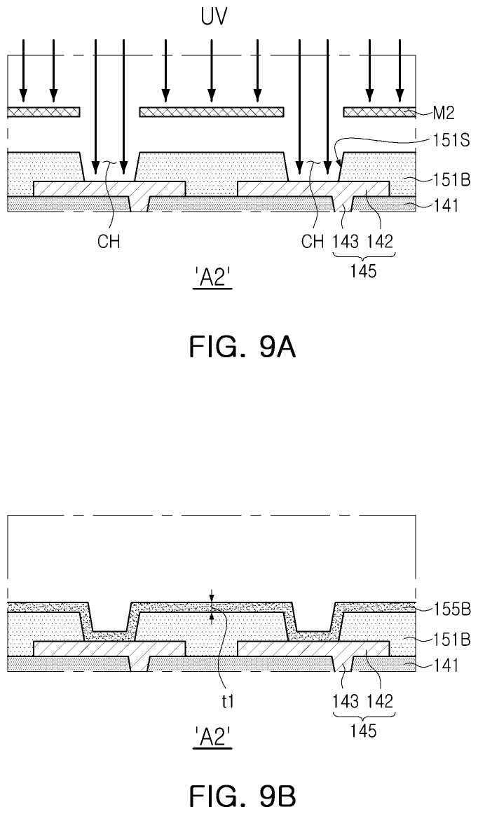

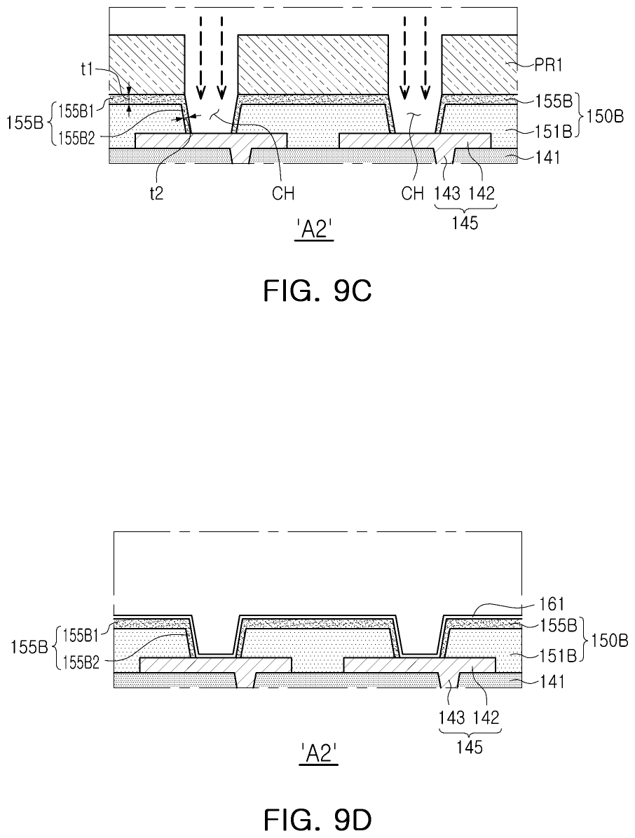

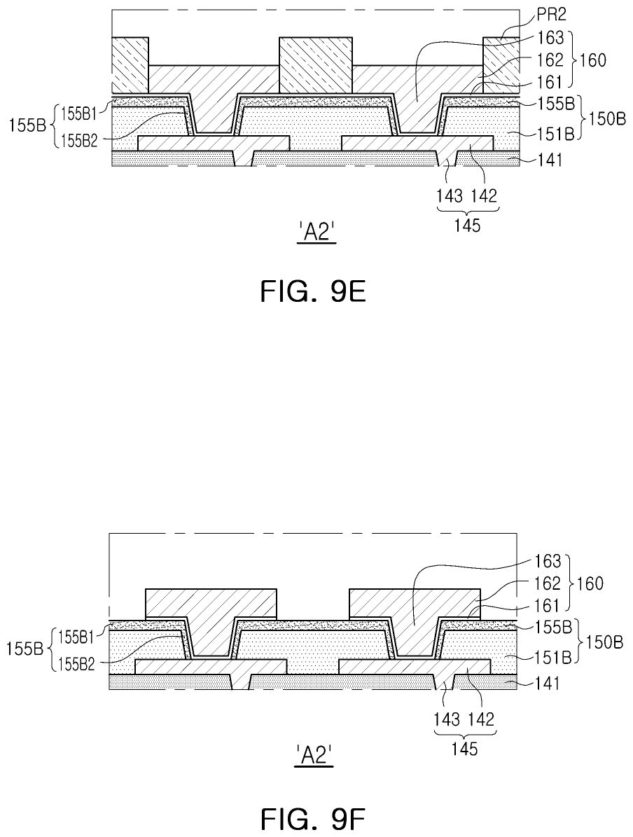

FIGS. 9A to 9F are cross-sectional diagrams illustrating main processes of a method of manufacturing the semiconductor package (particularly, a process of forming an UBM layer) illustrated in FIG. 7, illustrating the process in FIG. 4C of the method of manufacturing a semiconductor package illustrated in FIGS. 4A to 4D.

Referring to FIG. 9A, a second photosensitive insulating layer 151B′ covering the outermost redistribution pattern 142 may be formed on the second surface 140B of the redistribution substrate 140, and a contact hole CH may be formed.

The photosensitive insulating layer 151B may include or be formed of a positive photosensitive material. When the insulating layer 141 of the redistribution substrate 140 includes a photosensitive material, the photosensitive insulating layer 151B of the first protective insulating layer 150B may include the same material as that of the insulating layer 141 of the redistribution substrate 140. For example, the photosensitive insulating layer 151B and the insulating layer 141 may include a PID material. For example, the photosensitive insulating layer 151B may have a thickness in the range of 20 μm to 100 μm. In one example embodiment, a contact hole may be formed using a photolithography process using a mask M2. Since the contact hole CH formed in this example embodiment is formed using a partial exposure of a positive photosensitive material, the contact hole may have a shape having a width decreasing downwardly. That is, the internal sidewall 151S of the contact hole CH may have an inclined surface that tapers in a direction toward the redistribution layers 145.

Subsequently, referring to FIG. 9B, a non-photosensitive insulating layer may be formed to have a predetermined thickness on the photosensitive insulating layer 151B in which the contact hole is formed.

The non-photosensitive insulating layer 155 may be formed along an upper surface of the photosensitive insulating layer 151B and also an internal sidewall of the contact hole CH to be conformally formed in the contact hole CH. In this process, the non-photosensitive insulating layer 155 may also be formed on the bottom surface of the contact hole, for example, the exposed region of the redistribution pattern 142.

The non-photosensitive insulating layer 155B may be a material having an elongation higher than that of the photosensitive insulating layer 151B. For example, the non-photosensitive insulating layer 155B may include prepreg, ABF, FR-4, or BT. In example embodiments, the thickness t1 of the non-photosensitive insulating layer 155B may range from 10% to 40% of the total thickness of the first protective insulating layer 150B. In this process, the thickness t1 of the non-photosensitive insulating layer 155B may be substantially uniform on the upper surface of the photosensitive insulating layer 151B and on the internal surface of the contact hole CH.

Subsequently, referring to FIG. 9C, a portion of the non-photosensitive insulating layer 155B disposed on the bottom surface of the contact hole CH may be selectively removed.

In this process, a first photoresist pattern (PR1) exposing a contact hole CH may be formed on the upper surface of the first protective insulating layer 150B, and a portion of the non-photosensitive insulating layer 155B disposed on the bottom surface of the contact hole CH may be selectively removed using a selective removal process. Through this selective removal process, a partial region (also referred to as a “pad region”) of the redistribution pattern 142 may be exposed again through the contact hole CH. During this selective removal process, a portion of the non-photosensitive insulating layer 155B disposed on the inclined internal sidewall of the contact hole CH may be partially etched. Accordingly, after exposing the pad region of the redistribution pattern 142, the thickness t2 of the second portion 155B2 of the non-photosensitive insulating layer 155B disposed on the internal sidewalls of the plurality of contact holes CH may be less than the thickness t1 of the first portion 155B1 of the non-photosensitive insulating layer 155B disposed on the upper surface of the photosensitive insulating layer 151B. In example embodiments, in this process, the entire second portion 155B2 of the non-photosensitive insulating layer 155B may be removed.

Thereafter, a plurality of UBM layers 160 each connected to the pad region of the redistribution pattern 142 exposed to the first protective insulating layer 150B may be formed. For example, the plurality of UBM layers 160 may be formed through a series of processes in FIGS. 9D to 9F.

First, referring to FIG. 9D, a seed layer 161 may be formed on the first protective insulating layer 150B in which a contact hole CH is formed. The seed layer 161 may be formed over the upper surface of the first protective insulating layer 150B, the internal sidewall of the contact hole CH, and the region of the redistribution pattern 142 exposed on the bottom surface thereof. For example, the seed layer 161 may include or be formed of Ti/W or Ti/Cu.

Thereafter, referring to FIG. 9E, a second photoresist pattern PR2 having an opening for the UBM layer 160 may be formed on the seed layer 161, and the UBM layer 160 may be formed using the second photoresist pattern PR2.

In this example embodiment, the UBM layer 160 may contact the non-photosensitive insulating layer 155B with excellent toughness and elongation. When an external connection conductor is formed on the UBM pad 162, the non-photosensitive insulating layer 155B may also be in contact with the external connection conductor. Even when stress due to a difference in coefficient of thermal expansion is concentrated around the UBM pad 162, since the non-photosensitive insulating layer 155B in contact with the UBM pad 162 and the external connection conductor 180 has a relatively high degree of toughness and a relatively high elongation (e.g., 100% or more) as compared to the photosensitive insulating layer 151B, durability of the semiconductor package may improve.

Thereafter, referring to FIG. 9F, the second photoresist pattern PR2 may be removed, and a portion of the seed layer 161 exposed to the removed region may be removed.

The second photoresist pattern PR2 may be removed by a lift-off process. For example, the second photoresist pattern PR2 may be removed using an appropriate process such as an ashing process, an etching process, or a combination thereof. Additionally, a portion of the seed layer 161 exposed through etching may be removed.

Additionally, an external connection conductor 180 may be formed on the UBM layer 160. The external connection conductor 180 may include or be formed of a low melting point metal, for example, solder such as tin (Sn)-aluminum (Al)-copper (Cu). The external connection conductor 180 may include multiple layers or a single layer. For example, multiple layers may include copper pillars and solder, and a single layer may include tin-silver solder or copper.

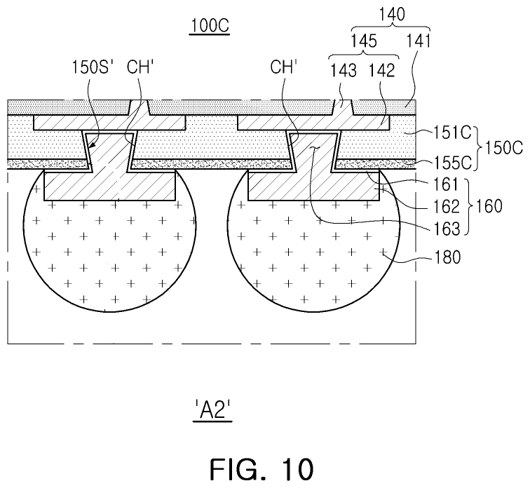

FIG. 10 is a cross-sectional diagram illustrating a portion of a semiconductor package according to a different example embodiment, corresponding to portion “A2” of the semiconductor package 100 in FIG. 7.

Referring to FIG. 10, the semiconductor package 100C in this example embodiment may be configured similarly to the example embodiment illustrated in FIGS. 7 and 8 other than the configuration in which the photosensitive insulating layer 151C is formed of a negative photosensitive material and the non-photosensitive insulating layer 155B is not present on the internal sidewall of the contact hole CH. Accordingly, the description in the example embodiment illustrated in FIGS. 7 and 8 may be combined with the description in the example embodiment of FIG. 10 unless otherwise indicated.

The first protective insulating layer 150C employed in this example embodiment may include a photosensitive insulating layer 151C disposed on the second surface 140B of the redistribution substrate 140 and a non-photosensitive insulating layer 155C on the photosensitive insulating layer 151C. The UBM pad 162 and the external connection conductor 180 may be in contact with the non-photosensitive insulating layer 155C having a relatively high degree of toughness and a relatively high elongation (e.g., 100% or more) as compared to the photosensitive insulating layer 151C.

Differently from the aforementioned example embodiment, the photosensitive insulating layer 151C employed in one example embodiment may include a negative photosensitive material. Accordingly, the contact hole CH′ may have a width decreasing toward the redistribution layers 145. That is, the internal sidewall of the photosensitive insulating layer 151C may have an inclined side surface 150S′ that tapers a direction away from the redistribution layers 145. In the structure of the contact hole CH, in the process of forming the non-photosensitive insulating layer 155C (see FIG. 9B), the non-photosensitive insulating layer 155C may not be formed on the internal sidewall 150S′ of the photosensitive insulating layer 151C. As such, the structure of the first protective insulating layer may be varied according to the type and process of forming the photosensitive insulating layer.

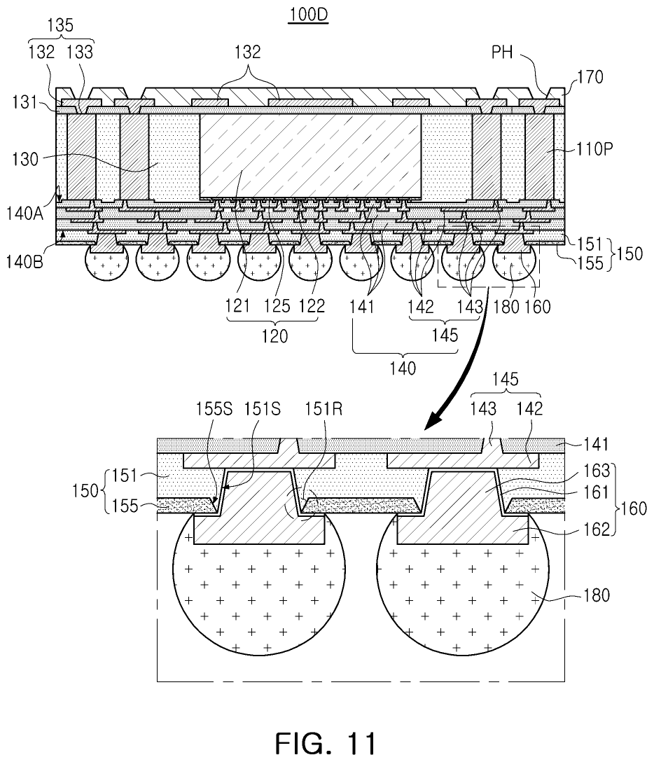

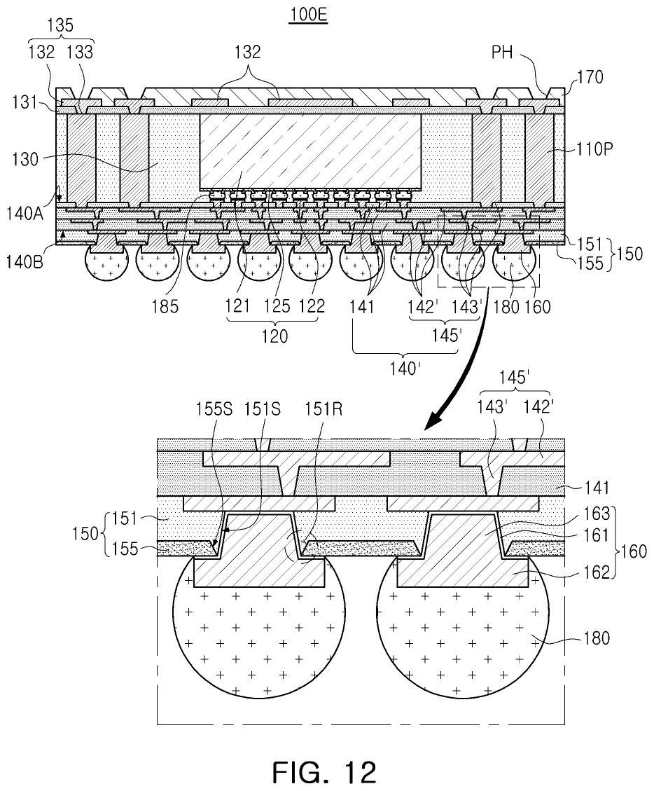

FIGS. 11 and 12 are cross-sectional diagrams illustrating a semiconductor package according to example embodiments.

Referring to FIG. 11, a semiconductor package 100D in the example embodiment may be configured similarly to the example embodiment illustrated in FIGS. 1 to 3 other than the configuration in which a conductive post 110P may be included as a vertical connection portion instead of the wiring structure of the frame. Accordingly, the description in the example embodiment illustrated in FIGS. 1 to 3 may be combined with the description in the example embodiment of FIG. 11 unless otherwise indicated. Also, the different structure of the conductive posts 110P may be used in the other embodiments described previously, for example the embodiments of FIGS. 3, 6, 7, and 8.

Differently from the aforementioned example embodiments, the semiconductor package 100D in the example embodiment may be a wafer level package. In the semiconductor package 100D, as a vertical interconnection element connecting the backside wiring layer 135 to the redistribution layers 145 of the redistribution substrate 140, the conductive post 110P may be used rather than the wiring structure of the frame. The conductive post 110P may be connected to the backside wiring layer 135. In the example embodiment, the conductive post 110P may have an upper surface substantially coplanar with the upper surface of the encapsulant 130 or may be exposed from the upper surface of the encapsulant 130. Also, an upper surface of the encapsulant 130 may have an upper surface substantially coplanar with the upper surface of the semiconductor chip 120. An insulating layer 131 such as PID may be disposed on the encapsulant 130, and the backside wiring layer 135 may include a redistribution via 133 penetrating through the insulating layer 131 and connected to the conductive post 110P, and a redistribution pattern 132 connected to the redistribution via 133 and disposed on the insulating layer 131. As such, the conductive post 110P may be configured to be directly connected to the vias 133 and 143 of the redistribution layers 135 and 145 disposed on the upper and lower surfaces thereof.

Similarly to the aforementioned example embodiment, the first protective insulating layer 150 may be provided in a structure in which a photosensitive insulating material and a non-photosensitive insulating material are combined. The first protective insulating layer 150 employed in one example embodiment may include a photosensitive insulating layer 151 disposed on the second surface 140B of the redistribution substrate 140 and a non-photosensitive insulating layer 155 formed at a surface of (e.g., buried, or on) the photosensitive insulating layer 151. At least a portion of regions in contact with the UBM pad 162 and the external connection conductor 180 may be formed with a non-photosensitive insulating layer 155. In example embodiments, the thickness of the non-photosensitive insulating layer 155 may range from 10% to 40% of the total thickness of the first protective insulating layer 150.

In the example embodiment of FIG. 11, a side surface 155S surrounding the contact hole CH of the non-photosensitive insulating layer 155 may have a first inclined surface inclined in a first direction so that the inclined surface tapers toward the redistribution layers 145. The internal sidewall 151S of the contact hole CH provided by the photosensitive insulating layer 151 may have a second inclined surface inclined in a second direction opposite to the first direction (e.g., that tapers in a direction away from the redistribution layers 145).

As such, when the photosensitive insulating layer 151 uses a positive photosensitive material, the side surface 155S of the non-photosensitive insulating layer 155 and the internal sidewall 151S of the photosensitive insulating layer 151 may have inclined surfaces inclined in opposite directions.

The photosensitive insulating layer 151 may have a portion 151R disposed between the UBM via 163 and the non-photosensitive insulating layer 155 in a direction parallel to the first surface 140A or the second surface 140B of the redistribution substrate 140. The portion 151R may be disposed around the lower end region of the UBM via 153.

FIG. 12 illustrates a wafer level package having a different structure from that of the wafer level package illustrated in FIG. 11.

Referring to FIG. 12, a semiconductor package 100E in this example embodiment may be configured similarly to the example embodiment illustrated in FIG. 11 other than the configuration in which the structure of the redistribution substrate 140′ is different, and the configuration in which the semiconductor chip 120 and the conductive posts 120P may be formed on a redistribution substrate 140′ which may be preferentially formed. Accordingly, descriptions in the example embodiments illustrated in FIGS. 11 and 1 to 3 may be combined with descriptions in the example embodiments unless otherwise indicated.

The semiconductor package 100E in this example embodiment may include a redistribution substrate 140′ having a different structure from that of the redistribution substrate 140 in the example embodiment illustrated in FIG. 11. The redistribution substrate 140′ employed in the example embodiment may be manufactured in advance prior to the mounting of the semiconductor chip 120. Specifically, the redistribution substrate 140′ may be formed from the second surface 140B to the first surface 140A by a build-up method, contrary to the build-up process illustrated in FIG. 4C.

A redistribution substrate 140′ employed in this example embodiment may include a plurality of redistribution layers 145′ disposed on a plurality of insulating layers (141) and connected to each other. The redistribution layers 145′ may include redistribution patterns 142′ disposed on the insulating layer 141 and redistribution vias 143′ penetrating through the insulating layer 141 and connecting redistribution patterns 142′ adjacent to each other. In this example embodiment, the redistribution vias 143′ may have an integrated structure with respective redistribution patterns 142 disposed thereon. Contrary to the redistribution vias 143 illustrated in FIG. 11, the redistribution vias 143′ may have a width decreasing toward the second surface 140B.

The semiconductor package 100D may include a conductive post 110P connecting the backside wiring layer 135 to the redistribution layer 145. In this example embodiment, the conductive post 110P may be formed on the redistribution pattern 142′ of the redistribution layer 145′. The connection pad 122 of the semiconductor chip 120 may be electrically connected to the pad region of the redistribution pattern 142′ adjacent to the first surface 140A by the conductive bump 185.

Similarly to the aforementioned example embodiment, the first protective insulating layer 150 may be provided in a structure in which a photosensitive insulating material and a non-photosensitive insulating material are combined. The first protective insulating layer 150 employed in the example embodiment may include a photosensitive insulating layer 151 disposed on the second surface 140B of the redistribution substrate 140 and a non-photosensitive insulating layer 155 buried in the photosensitive insulating layer 151. At least a portion of regions in contact with the UBM pad 162 and the external connection conductor 180 may be formed with a non-photosensitive insulating layer 155. Also, similarly to the aforementioned example embodiment, the side surface 155S surrounding the contact hole CH of the non-photosensitive insulating layer 155 may have a first inclined surface inclined in a first direction toward the redistribution layers 145, and the internal sidewall 151S of the contact hole CH provided by the photosensitive insulating layer 151 may have a second inclined surface inclined in a second direction opposite to the first direction.

As such, when the photosensitive insulating layer 151 uses a positive photosensitive material, the side surface 155S of the non-photosensitive insulating layer 155 and the internal sidewall 151S of the photosensitive insulating layer 151 may have inclined surfaces inclined in opposite directions. The photosensitive insulating layer 151 may have a portion 151R disposed between the UBM via 163 and the non-photosensitive insulating layer 155 in a direction parallel to the first surface 140A or the second surface 140B of the redistribution substrate 140.

The semiconductor packages 100D and 100E illustrated in FIGS. 11 and 12 may include the first protective insulating layer and the UBM layer similar to the examples in FIG. 1, but the first protective insulating layer and the UBM layer may be combined with each other in another example embodiment.

According to the aforementioned example embodiments, to improve efficiency and precision of the manufacturing process, by forming the insulating layer for the UBM layer as a photosensitive insulating layer, and partially including a non-photosensitive insulating layer having excellent toughness and elongation around the UBM layer, mechanical damage such as cracks due to thermal stress may be effectively prevented.

While the example embodiments have been illustrated and described above, it will be apparent to those skilled in the art that modifications and variations could be made without departing from the scope of the present invention as defined by the appended claims.

1. A semiconductor package, comprising:
a redistribution substrate having a first surface and a second surface opposite to each other, and including a plurality of first photosensitive insulating layers and a plurality of redistribution layers disposed among the plurality of first photosensitive insulating layers, the plurality of redistribution layers electrically connected to each other;
at least one semiconductor chip disposed on the first surface of the redistribution substrate and including a plurality of contact pads electrically connected to the plurality of redistribution layers;
a protective insulating layer including a second photosensitive insulating layer disposed on the second surface of the redistribution substrate and having a plurality of contact holes, the second photosensitive insulating layer including a first surface facing and adjacent to the redistribution substrate and a second surface opposite the first surface;
a non-photosensitive insulating layer buried in the second photosensitive insulating layer, wherein the non-photosensitive insulating layer is provided as an outer surface of the protective insulating layer and is adjacent to the second surface of the second photosensitive insulating layer; and
a plurality of under bump metallurgy (UBM) connectors disposed on the protective insulating layer and connected to the plurality of redistribution layers through the plurality of contact holes, respectively,
wherein a side surface of the non-photosensitive insulating layer surrounds each of the plurality of contact holes from a plan view and has a first inclined surface inclined with respect to a surface of the plurality of redistribution layers in a first direction, and an internal sidewall of each of the plurality of contact holes of the second photosensitive insulating layer has a second inclined surface inclined with respect to the surface of the plurality of redistribution layers in a second direction opposite to the first direction.

2. The semiconductor package of claim 1, wherein the non-photosensitive insulating layer has a surface coplanar with a surface of the second photosensitive insulating layer.

3. The semiconductor package of claim 1, wherein each of the plurality of UBM connectors includes a UBM pad disposed on the protective insulating layer and a UBM via connected to the UBM pad and disposed in a respective contact hole of the plurality of contact holes.

4. The semiconductor package of claim 3, wherein for each UBM via, the second photosensitive insulating layer has a portion disposed between the UBM via and the non-photosensitive insulating layer in a direction parallel to the first surface of the redistribution substrate.

5. The semiconductor package of claim 3, wherein the side surface of the non-photosensitive insulating layer surrounding each of the plurality of contact holes contacts a respective UBM via.

6. The semiconductor package of claim 1, wherein the non-photosensitive insulating layer has a thickness of 10% to 40% of a total maximum thickness of the protective insulating layer.

7. The semiconductor package of claim 1, further comprising:
a plurality of external connection conductors disposed on the plurality of UBM connectors, respectively,
wherein the plurality of external connection conductors contact the non-photosensitive insulating layer.

8. The semiconductor package of claim 1, wherein the non-photosensitive insulating layer has a coefficient of thermal expansion (CTE) higher than a CTE of the second photosensitive insulating layer.

9. The semiconductor package of claim 1, wherein the non-photosensitive insulating layer includes an epoxy resin or an ABF resin.

10. The semiconductor package of claim 1, wherein the second photosensitive insulating layer includes a positive photosensitive material.

11. The semiconductor package of claim 1, wherein the second photosensitive insulating layer includes the same material as a material of the first photosensitive insulating layers.

12. The semiconductor package of claim 1, further comprising:
an encapsulant disposed on the first surface of the redistribution substrate and surrounding the at least one semiconductor chip.

13. The semiconductor package of claim 12, further comprising:
a vertical interconnection portion disposed on the first surface of the redistribution substrate and connected to the redistribution layers, and
an additional redistribution layer disposed on the encapsulant and connected to the vertical interconnection portion.

14. A semiconductor package, comprising:
a redistribution substrate having a first surface and a second surface opposite to each other, and including a plurality of insulating layers and a plurality of redistribution layers disposed among the plurality of insulating layers, the plurality of redistribution layers electrically connected to each other;
at least one semiconductor chip disposed on the first surface of the redistribution substrate and having a plurality of contact pads electrically connected to the plurality of redistribution layers;
a protective insulating layer including a photosensitive insulating layer disposed on the second surface of the redistribution substrate and having a plurality of contact holes, and a non-photosensitive insulating layer buried in the photosensitive insulating layer, wherein the non-photosensitive insulating layer is provided as an outer surface of the protective insulating layer; and
a plurality of under bump metallurgy (UBM) connectors each including a UBM pad disposed on the protective insulating layer and a UBM via disposed in a respective contact hole of the plurality of contact holes and electrically connected to the plurality of redistribution layers,
wherein for each UBM via, the photosensitive insulating layer has a portion disposed between the UBM via and the non-photosensitive insulating layer in a direction parallel to the first surface of the redistribution substrate.

15. The semiconductor package of claim 14, wherein the non-photosensitive insulating layer has a surface coplanar with a surface of the photosensitive insulating layer, and side surfaces adjacent to the plurality of contact holes and inclined in a first direction so that the side surfaces taper in a direction away from the plurality of redistribution layers.

16. The semiconductor package of claim 15, wherein each of the plurality of contact holes has internal sidewalls surrounded by the photosensitive insulating layer and inclined in a second direction opposite to the first direction.

17-20. (canceled)

21. A semiconductor package, comprising:
a redistribution substrate having a first surface and a second surface opposite to each other, and including a plurality of first photosensitive insulating layers and a plurality of redistribution layers disposed among the plurality of first photosensitive insulating layers;
at least one semiconductor chip disposed on the first surface of the redistribution substrate and including a plurality of contact pads electrically connected to the plurality of redistribution layers;
a protective insulating layer having a first surface facing the second surface of the redistribution substrate and a second surface opposite the first surface, and including a second photosensitive insulating layer disposed on the second surface of the redistribution substrate and having a plurality of contact holes, and a non-photosensitive insulating layer disposed at an outer surface of the second photosensitive insulating layer to form the second surface of the protective insulating layer; and
a plurality of under bump metallurgy (UBM) connectors each having a UBM pad disposed on the protective insulating layer and a UBM via disposed in a respective contact hole of the plurality of contact holes and electrically connected to a redistribution signal line of the plurality of redistribution layers,
wherein the non-photosensitive insulating layer contacts each UBM pad.

22. The semiconductor package of claim 21, wherein:
the non-photosensitive insulating layer is disposed on an upper surface of each UBM pad and on an internal sidewall of each of the plurality of contact holes.

23. The semiconductor package of claim 22, wherein:
a portion of the non-photosensitive insulating layer on the internal sidewall each of the plurality of contact holes has a thickness less than a thickness of a portion of the non-photosensitive insulating layer on the upper surface of each UBM pad.

24. The semiconductor package of claim 22, wherein:
the non-photosensitive insulating layer has a thickness of 10% to 40% of a total maximum thickness of the protective insulating layer.

25-31. (canceled)
